(19) United States
(12) Patent Application Publication
(10) Pub. No.: US 2017/0184680 A1
(43) Pub. Date: Jun. 29, 2017

(54) SENSOR MANAGEMENT APPARATUS AND METHOD

(71) Applicant: Samsung Electronics Co., Ltd., Suwon-si (KR)

(72) Inventors: Kae Weon YOU, Hwaseong-si (KR); Sang Do PARK, Seoul (KR)

(73) Assignee: Samsung Electronics Co., Ltd., Suwon-si (KR)

(21) Appl. No.: 15/376,709

(22) Filed: Dec. 13, 2016

(30) Foreign Application Priority Data
Dec. 29, 2015 (KR) 10-2015-0188854

(51) Int. Cl. G01R 31/36

(52) U.S. Cl. CPC G01R 31/3651; G01R 31/3624; G01R 31/3658

(57) ABSTRACT

A sensor management system includes a data collector configured to collect various types of data from a plurality of sensors, and an estimator configured to estimate other types of data based on two or more types of the collected data.

### CROSS-REFERENCE TO RELATED APPLICATIONS

This application claims the benefit under 35 USC 119(a) of Korean Patent Application No. 10-2015-0188854 filed on Dec. 29, 2015, in the Korean Intellectual Property Office, the entire disclosure of which is incorporated herein by reference for all purposes.

### BACKGROUND

1. Field

The following description relates to a battery management system.

2. Description of Related Art

A battery management system (BMS) determines the internal status of a battery from sensors mounted inside the battery. The BMS may be designed to operate with a plurality of duplicate sensors mounted in the battery to prevent a malfunction caused by the fault of a single sensor, so that even if a fault occurs in one sensor, the fault can be compensated by other sensors of the same type that are operating normally.

Stable operation of a sensor is important for the BMS to be able to accurately determine the internal status of the battery. A malfunction caused by a fault in a sensor can be prevented by providing duplicate sensors of the same type. However, providing duplicate sensors necessarily increases the cost and volume of hardware due to the additional sensors and additional wires connecting the additional sensors to the BMS.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a sensor management apparatus includes a data collector configured to collect various types of data from a plurality of sensors; and an estimator configured to estimate other types of data based on two or more types of the collected data.

At least some of the plurality of sensors may be inside a battery; and the data collector may be further configured to collect, as at least part of the various types of data, any one or any combination of any two or more of voltage data, current data, and temperature data sensed by at least some of the sensors inside the battery.

The estimator may be further configured to estimate, as part of the other types of data, a third type of data correlated with a first type of data and a second type of data different from the first type of data based on the first type of data and the second type of data.

There may be an interdependence between data patterns of the first type of data and the third type of data, and an interdependence between data patterns of the second type of data and the third type of data; and the estimator may be further configured to estimate the third type of data based on the first type of data and the second type of data using a pre-stored data estimation model trained based on the interdependences.

The sensor management apparatus may further include a preprocessor configured to train a data estimation model for each sensor of the plurality of sensors.

The preprocessor may be further configured to analyze various types of data sensing values and data patterns of the collected data based on various battery operation patterns, and based on a result of the analyzing, train the data estimation model for each sensor using the two or more types of the collected data.

The sensor management apparatus may further include a memory configured to store the data estimation model for each sensor; and a buffer configured to store the various types of data sensing values and data patterns of the collected data.

The data estimation model for each sensor may be based on any one or any combination of any two or more of a neural network (NN), a deep neural network (DNN), a support vector machine (SVM), and a Gaussian process regression (GPR).

The data estimation model for each sensor may be a DNN-based data estimation model; and the preprocessor may be further configured to input the two or more types of the collected data to the DNN-based data estimation model, and train the DNN-based data estimation model to estimate data of a predetermined sensor based on a data correlation between the data of the predetermined sensor and the two or more types of the collected data.

The estimator may be further configured to estimate data of a predetermined sensor of the plurality of sensors based on the two or more types of the collected data; and the apparatus may further include a sensor manager configured to compare actual measurement data acquired from the predetermined sensor with the estimated data of the predetermined sensor, and determine whether there is a fault in the predetermined sensor based on a result of the comparing.

In another general aspect, a sensor management method includes collecting various types of data from a plurality of sensors; and estimating other types of data based on two or more types of the collected data.

At least some of the plurality of sensors may be inside a battery; and the collecting of the various types of data may include collecting, as at least part of the various types of data, any one or any combination of any two or more of voltage data, current data, and temperature data sensed by at least some of the sensors inside the battery.

The estimating of other types of data may include estimating, as part of the other types of data, a third type of data correlated with a first type of data and a second type of data different from the first type of data based on the first type of data and the second type of data.

There may be an interdependence between data patterns of the first type of data and the second type of data, and an interdependence between data patterns of the second type of data and the third type of data; and the estimating of the third type of data may include estimating the third type of data based on the first type of data and the second type of data using a pre-stored data estimation model trained based on the interdependences.

The sensor management method may further include training a data estimation model for each sensor of the plurality of sensors.

The training may include analyzing various types of data sensing values and data patterns of the collected data based on various battery operation patterns; and, based on a result of the analyzing, training the data estimation model for each sensor using the two or more types of the collected data.

The data estimation model for each sensor may be based on any one or any combination of any two or more of a neural network (NN), a deep neural network (DNN), a support vector machine (SVM), and a Gaussian process regression (GPR).

The data estimation model for each sensor may be a DNN-based estimation model; and the training may include inputting the two or more types of the collected data to the DNN-based data estimation model; and training the DNN-based estimation model to estimate data of a predetermined sensor based on a data correlation between the data of the predetermined sensor and the two or more types of the collected data.

The estimating may include estimating data of a predetermined sensor of the plurality of sensors based on the two or more types of the collected data; and the method may further include comparing actual measurement data acquired from the predetermined sensor with the estimated data of the predetermined sensor; and determining whether there is a fault in the predetermined sensor based on a result of the comparing.

In another general aspect, a non-transitory computer-readable storage medium stores instructions that, when executed by a processor, cause the processor to perform the sensor management method described above.

In another general aspect, a sensor management apparatus includes a processor configured to collect different types of data from a plurality of sensors, and estimate data of a faulty sensor based on two or more other types of data of the collected data.

The sensor management apparatus may further include a memory configured to store instructions; and the processor may be further configured to execute the instructions to configure the processor to collect different types of data from a plurality of sensors, and estimate data of a faulty sensor based on two or more other types of data of the collected data.

There may be only one sensor for each different type of data.

The processor may be further configured to estimate the data of the faulty sensor based on two or more other types of data of the collected data that are correlated with data of the faulty sensor obtained while the faulty sensor is operating normally.

The processor may be further configured to estimate the data of the faulty sensor based on two or more other types of data of the collected data that are correlated with the data of the faulty sensor using a data estimation model for the faulty sensor that is trained based on the correlation between the data of the faulty sensor obtained while the faulty sensor is operating normally and the two or more other types of data of the collected data that are correlated with the data of the faulty sensor obtained while the faulty sensor is operating normally.

The processor may be further configured to train the data estimation model for the faulty sensor based on the data of the faulty sensor obtained while the faulty sensor is operating normally and the two or more other types of data of the collected data that are correlated with the data of the faulty sensor obtained while the faulty sensor is operating normally.

Other features and aspects will be apparent from the following detailed description, the drawings, and the claims.

### BRIEF DESCRIPTION OF THE DRAWINGS

FIG. 1 is a diagram illustrating an example of a sensor management apparatus.

FIG. 2 is a detailed diagram illustrating an example of a sensor management apparatus.

FIG. 3 is a diagram illustrating an example of a graph showing an interdependence between data patterns.

FIG. 4 is a diagram illustrating an example of inputting sensing data to a DNN-based data estimation model.

FIG. 5 is a diagram illustrating an example of comparing actual measurement data acquired by a sensor manager with estimated data that is estimated based on two or more other types of data.

FIG. 6 is a flowchart illustrating an example of a sensor management method.

FIG. 7 is a flowchart illustrating an example of a method of training a data estimation model.

FIG. 8 is a flowchart illustrating an example of a sensor management method using a data estimation model.

FIG. 9 is a detailed diagram illustrating another example of a sensor management apparatus.

Throughout the drawings and the detailed description, the same reference numerals refer to the same elements. The drawings may not be to scale, and the relative size and depiction of elements in the drawings may be exaggerated for clarity, illustration, and convenience.

### DETAILED DESCRIPTION

The following description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

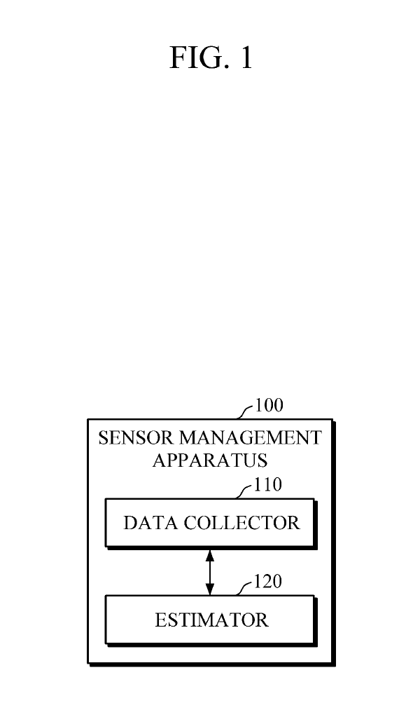

FIG. 1 is a diagram illustrating an example of a sensor management apparatus 100. The sensor management apparatus 100 includes a data collector 110 and an estimator 120.

The data collector 110 collects various types of data from a plurality of sensors. For example, the data collector 110 collects any one or any combination of any two or more of current data, voltage data, and temperature data sensed by a plurality of sensors inside a battery. In addition to this example, there may be other sensors inside the battery that sense other types of data relating to an internal state of the battery. The data collector 110 may periodically collect sensing data from the sensors. Although this example refers to sensors inside a battery, some or all of the sensors may be mounted outside the battery.

The estimator 120 estimates other types of data based on two or more types of the collected data. In one example, the estimator 120 estimates data of a predetermined sensor from data collected from two or more other types of sensors.

In one example, based on a first type of data and a second type of data different from the first type of data, the estimator 120 estimates a third type of data correlated with the first type of data and the second type of data. For example, based on current data and voltage data, the estimator 120 estimates temperature data correlated with the current data and the voltage data. In another example, the estimator 120 estimates current data correlated with voltage data and temperature data based on the voltage data and the temperature data. However, these are merely examples, and there is no limitation on a type of data that can be estimated by the estimator 120.

If data of a predetermined type of sensor can be estimated based on data of other types of sensors, it is not necessary to provide duplicate sensors of the predetermined type to compensate for a fault in a sensor of the predetermined type, thus reducing hardware costs.

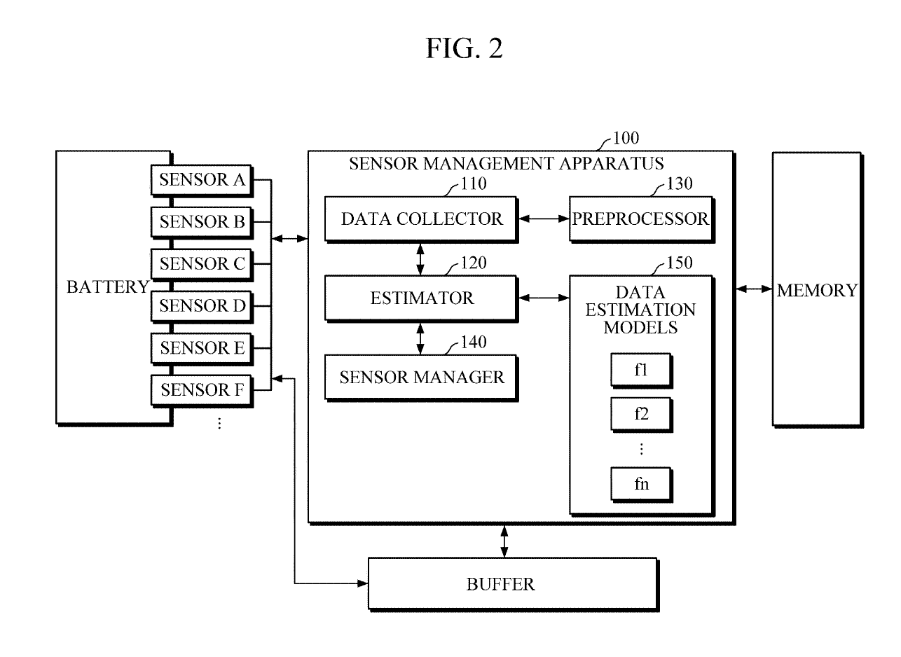

FIG. 2 is a detailed diagram illustrating an example of a sensor management apparatus. A sensor management apparatus 100 includes a data collector 110, an estimator 120, a preprocessor 130, a sensor manager 140, and data estimation models 150, and is connected to a plurality of sensors A to F, a buffer, and a memory.

The battery may be a battery cell, a battery module including several battery cells, a battery pack including several battery modules, or any other type of battery. Hereinafter, all of these types of batteries are simply referred to as a battery.

Referring to FIG. 2, the data collector 110 collects sensing data acquired from a plurality of sensors provided in the battery, e.g., sensors A to F in the example in FIG. 2. The buffer temporarily stores various types of data sensing values, data patterns, and estimation values of the collected data; and the data collector 110 collects the data that is temporarily stored in the buffer.

The estimator 120 estimates other types of data based on two or more types of the collected data. For example, the estimator 120 estimates data of a predetermined sensor based on two or more other types of data of the collected data that are correlated with the data of the predetermined sensor.

For example, based on current data (a first type of data) and voltage data (a second type of data) that are different from each other, the estimator 120 estimates temperature data (a third type of data) that is different from the current data and the voltage data. There is a data correlation between the current data and the temperature data, and between the voltage data and the temperature data. That is, the temperature data is correlated with both the current data and the temperature data.

There is an interdependence between data patterns of sensing data of current, voltage, and temperature that may vary depending on a type of battery operation. For example, the interdependence between the data patterns of the sensing data of current, voltage, and temperature during a battery charging operation is different from the interdependence between the data patterns of the sensing data of current, voltage, and temperature during a battery discharging operation. Based on two or more types of data, the estimator 120 estimates other types of data that are different from the two or more types of data, but are correlated with the two or more types of data.

In one example, the estimator 120 estimates the third type of data based on the first type of data and the second type of data using pre-stored data estimation models 150. A data estimation model 150 is provided for each sensor. The estimator 120 estimates the third type of data by inputting the first type of data and the second type of data to the data estimation model 150 for the sensor for the third type of data, which is trained in advance. The data estimation model 150 for each sensor may be trained in a preprocessing operation or acquired from the outside.

Referring to FIG. 2, the preprocessor 130 generates data estimation models 150 f1 for sensor A, f2 for sensor B, and so on. The preprocessor 130 generates a data estimation model 150 for each of the plurality of sensors A to F, although not all of these data estimation models are shown in FIG. 2, and in general, generates a data estimation model 150 fn for a sensor n.

The preprocessor 130 is, for example, a calculation module of a processor, and trains the data estimation model 150 for each sensor of the plurality of sensors. The preprocessor 130 analyzes various types of the data sensing values and data patterns of the collected data based on various battery operation patterns. Based on the results of the analysis, the preprocessor 130 trains the data estimation model 150 for each sensor using two or more other types of data that are correlated with the data sensed by the sensor for which the data estimation model 150 is being trained.

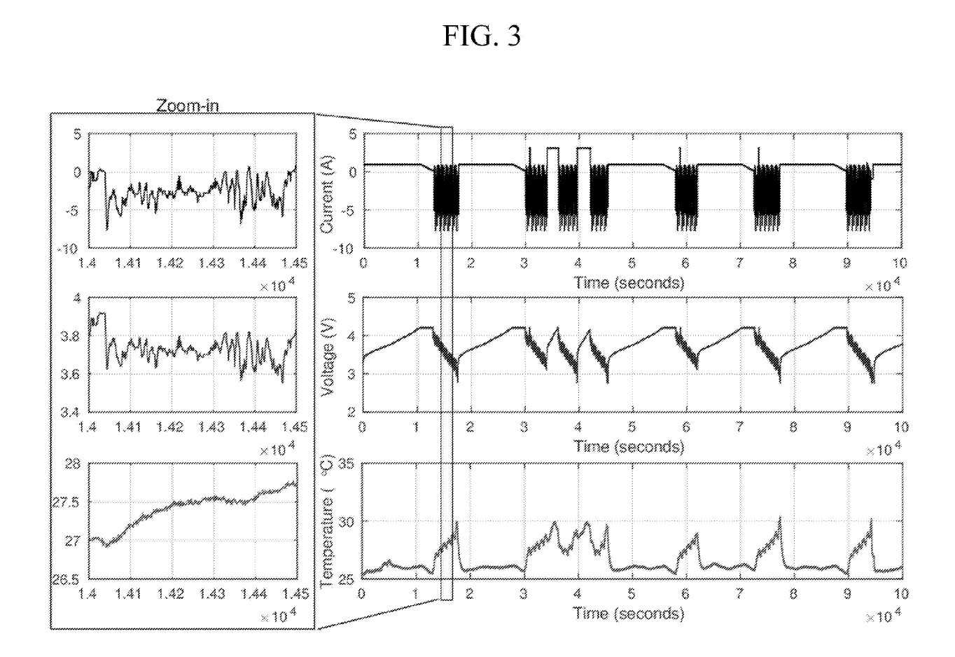

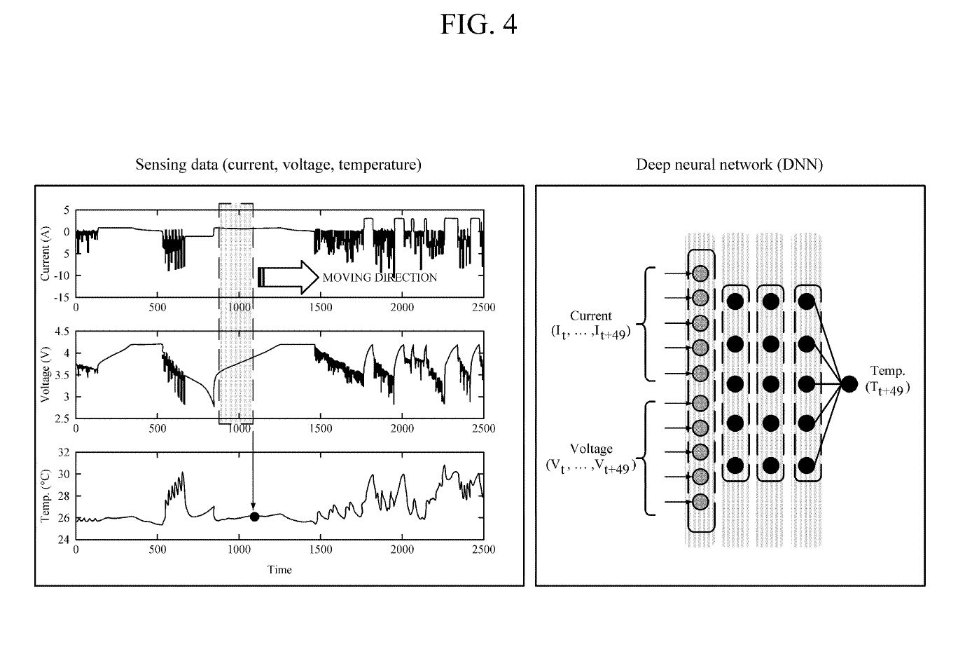

The preprocessor 130 analyzes the interdependence between data patterns of various types of data in accordance with a type of battery operation, and detailed examples thereof will be described later with reference to FIGS. 3 and 4.

Each of the data estimation models 150 may be based on any one or any combination of any two or more of a neural network (NN), a deep neural network (DNN), a support vector machine (SVM), and a Gaussian process regression (GPR). In one example, the preprocessor 130 trains a DNN-based data estimation model 150 for each sensor by inputting the various types of data collected by the data collector 110 to the DNN-based data estimation model 150. For example, the preprocessor 130 inputs two or more types of data to the DNN-based data estimation model 150 for a predetermined sensor, and based on a data correlation between data sensed by the predetermined sensor and the two or more types of data, trains a parameter set for estimating the data of a predetermined sensor from the two or more types of data.

The sensor management apparatus 100 stores the data estimation models 150 and parameters thereof trained by the preprocessor 130 in an internal memory or an external memory as the pre-stored data estimation models 150 that are used by the estimator 120 to estimate the other types of data based on two or more types of the collected data. The memory may be a non-volatile memory.

The sensor manager 140 determines whether there is a fault in a predetermined sensor by comparing actual measurement data acquired from the predetermined sensor with data that is estimated by the estimator 120 based on two or more other types of data that are correlated with the actual measurement data.

For example, if a difference between the actual measurement data and the estimated data is greater than a predetermined threshold, the sensor manager 140 determines that the predetermined sensor has a fault, or performs other operations to determine whether there is fault in the predetermined sensor. In one example, when the sensor manager 140 determines that a predetermined sensor has a fault or is malfunctioning, the sensor manager 140 may send a notification about the fault in the predetermined sensor to a user.

Since it is not necessary to provide duplicate sensors of the same type to compensate for a fault in a sensor of that type, the costs and volume of hardware may be reduced.

FIG. 3 is a diagram illustrating an example of a graph showing an interdependence between data patterns. FIG. 3 illustrates an example of current data, voltage data, and temperature data on the Y axis according to time on the X axis.

The preprocessor 130 analyzes the data patterns in FIG. 3 to identify data correlations between the current data and the voltage data, between the voltage data and the temperature data, and between the current data and the temperature data.

The current data, voltage data, and temperature data measured inside a battery have regular data patterns according to a type of battery operation (a battery charging period or a battery discharging period). Referring to FIG. 3, the current data changes repeatedly between a positive value during a battery charging period and a negative value during a battery discharging period. The voltage data increases during the battery charging period, and decreases during the battery discharging period. The temperature data stays within a range of a predetermined value (a temperature of a chamber in which the current data, voltage data, and temperature data are measured, i.e., 25° C. in the example in FIG. 3) during the battery charging period, and increases during the battery discharging period. The current data, the voltage data, and the temperature data change according to the interdependence therebetween. The interdependence may change depending on a type of battery operation. As can be seen from FIG. 3, the interdependence between the current data, the voltage data, and the temperature data during the battery charging period is different from the interdependence between the current data, the voltage data, and the temperature data during the battery discharging period. Although it has been described above that a data estimation model 150 is provided for each sensor, this is only an example. In another example, two data estimation models 150 may be provided for a temperature sensor, one data estimation model 150 for use during the battery charging period, and another data estimation model 150 for use during the battery discharging period.

The left graph in FIG. 3 is a zoomed-in portion of the right graph in FIG. 3 showing current data, voltage data, and temperature data within a period of time from 1.4×10⁴ s to 1.45×10⁴ s. The graph shows a portion of a battery discharging period during which the current has a negative value, the voltage decreases, and the temperature increases. Each of the current data, voltage data, and temperature data are correlated with the other ones of the current data, voltage data, and temperature data. Based on two or more types of data, the preprocessor 130 trains a data estimation model 150 for estimating another type of data having a data pattern having an interdependence with data patterns of the two or more other types of data. However, FIG. 3 is just one example, and data patterns of various data according to a type of battery operation may occur in various ways.

FIG. 4 is a diagram illustrating an example of inputting sensing data to a DNN-based data estimation model. Referring to FIG. 2, a preprocessor 130 trains a deep neural network (DNN)-based data estimation model 150 for estimating data of a predetermined sensor by inputting the sensing data on the left side of FIG. 4 to the deep neural network (DNN)-based data estimation model 150 on the right side of FIG. 4.

Referring to the left side of FIG. 4, an example of data patterns of current data, voltage data, and temperature data is illustrated. The right side of FIG. 4 illustrates an example of a DNN-based data estimation model 150. The preprocessor 130 inputs, to the DNN-based data estimation model 150, current data (A) and voltage data (V) measured during a predetermined period of time inside a rectangular box that moves to the right as indicated by the arrow, and trains the DNN-based data estimation model 150 for estimating temperature data at a specific point in time indicated by the black dot on the graph of the temperature data. The preprocessor 130 trains the DNN-based data estimation model 150 for each sensor, and stores a parameter set of the DNN-based data estimation model 150.

In the example in FIG. 4, the preprocessor 130 inputs, to the DNN-based data estimation model 150, 50 current data samples It through Iₜ₊₄₉ and 50 voltage samples Vₜ through Vₜ₊₄₉ measured at points in time t through t+49 during the predetermined period of time, and trains the DNN-based data estimation model 150 to estimate one temperature data sample Tₜ₊₄₉ at a specific point in time t+49. Thus, in the example in FIG. 4, the preprocessor 130 trains the DNN-based data estimation model 150 to estimate one temperature data sample based on 50 current data samples and 50 voltage data samples. However, this is merely an example, and the DNN-based estimation model 150 may train the DNN-based data estimation model 150 to estimate one temperature data sample based on greater or fewer than 50 current data samples and 50 voltage data samples.

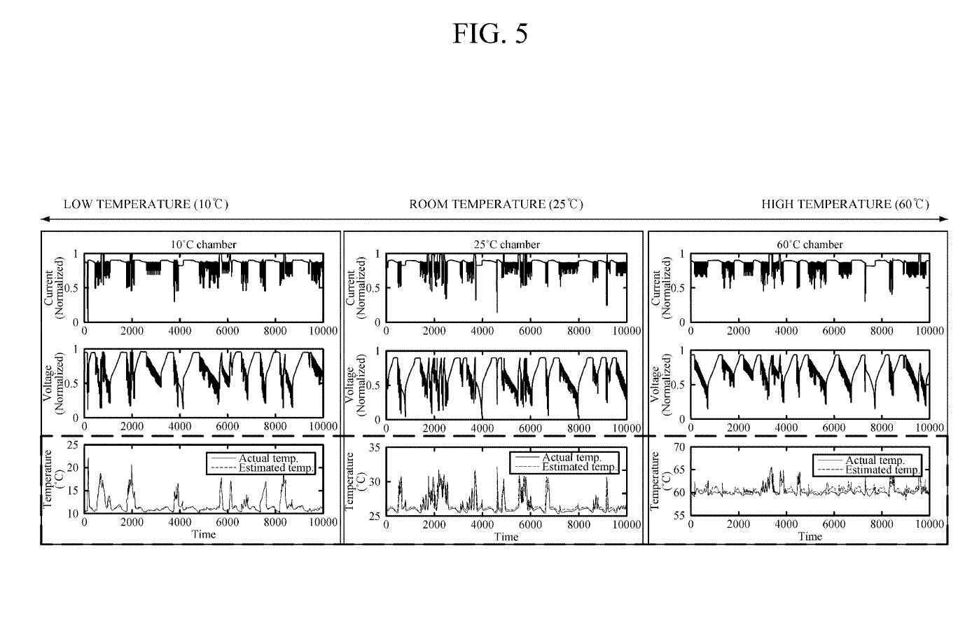

FIG. 5 is a diagram illustrating an example of comparing actual measurement data acquired by a sensor manager with estimated data that is estimated based on two or more other types of data.

FIG. 5 illustrates examples of data patterns of current data and voltage data. The bottom graph of FIG. 5 illustrates a graph of actual temperature data that is measured by a sensor in a chamber maintained at a low temperature (10° C.), room temperature (25° C.), and a high temperature (60° C.); and a graph of estimated temperature data that is estimated based on the current data and the voltage data.

Referring to FIG. 5, the graph of the estimated temperature data estimated based on the current data and the voltage data by a sensor management apparatus 100 is similar to the graph of the actual temperature data measured by a sensor. In this case, the sensor management apparatus 100 determines that a temperature sensor is operating normally. The sensor management apparatus 100 determines whether the temperature sensor has a fault or is malfunctioning based on the comparison of the actual temperature data with the estimated temperature data.

In addition to the example described above, the sensor management apparatus 100 generates a corresponding data estimation model 150 for each of the various sensors inside a battery and determines whether each sensor has a fault based on a data correlation between data sensed by the sensor and data sensed by other types of sensors.

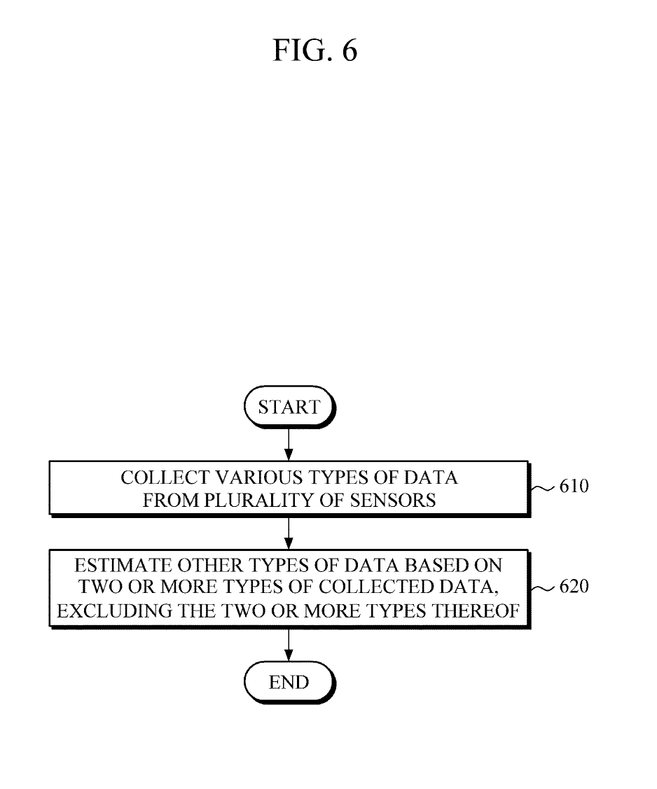

FIG. 6 is a flowchart illustrating an example of a sensor management method. Hereinafter, a sensor management method using a sensor management apparatus 100 will be described in detail with reference to FIGS. 1 and 6.

First, a data collector 110 collects various types of data from a plurality of sensors in 610. For example, the data collector 110 collects various types of comprising any one or any combination of any two or more of current data, voltage data, and temperature data sensed by a plurality of sensors inside a battery. In addition to this example, there may be other sensors inside the battery that can sense other types of data relating to an internal state of the battery. The data collector 110 may periodically collect sensing data from the sensors. Although this example refers to sensors inside the battery, some or all of the sensors may be outside the battery.

Then, the estimator 120 estimates other types of data based on two or more types of the collected data in 620. The estimator 120 estimates data of a predetermined sensor based on data collected from two or more other types of sensors.

In one example, based on a first type of data and a second type of data different from the first type of data, the estimator 120 estimates a third type of data that is correlated with the first type of data and the second type of data. For example, based on current data and voltage data, the estimator 120 estimates temperature data that is correlated with the current data and the voltage data. In another example, based on voltage data and temperature data, the estimator 120 estimates current data that is correlated with the voltage data and the temperature data. In another example, based on current data and temperature data, the data estimator 120 estimates voltage data that is correlated with the current data and the temperature data. There is no limitation on a type of data that can be estimated by the estimator 120.

If data of a predetermined sensor can be estimated based on other types of data, it is not necessary to provide duplicate sensors of the same type to compensate for a fault in a sensor of that type, thus reducing hardware costs and volume.

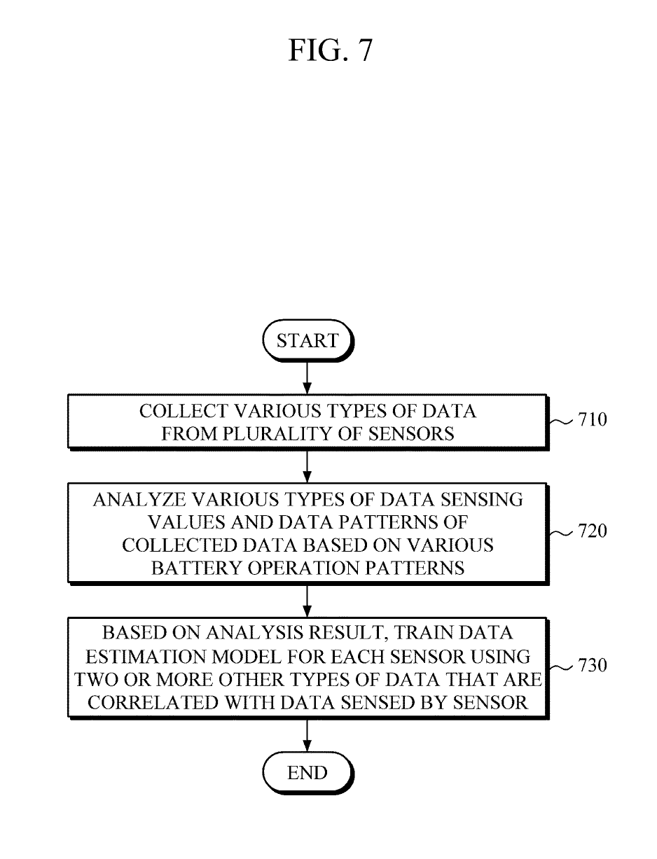

FIG. 7 is a flowchart illustrating an example of a method of training a data estimation model. A preprocessor 130 trains a data estimation model 150 for each sensor. Hereinafter, a method of training a data estimation model for each sensor using the preprocessor 130 will be described with reference to FIG. 2.

First, a data collector 110 collects various types of data from a plurality of sensors in 710.

Then, the preprocessor 130 analyzes various types of data sensing values and data patterns of the collected data based on various battery operation patterns in 720.

Then, based on the analysis result, the preprocessor 130 trains a data estimation model 150 for each sensor using two or more other types of data that are correlated with the data sensed by the sensor for which the data estimation model 150 is being trained in 730. For example, the preprocessor 130 trains the data estimation model 150 based on the interdependence between data patterns of various types of data in accordance with a type of battery operation. The training may also take into account other factors, such as whether the battery is a battery cell, a battery module including several battery cells, or a battery pack including several battery modules; an ambient temperature in which the battery is operating; and a maximum capacity of the battery. However, these are merely examples, and other factors affecting the operation of the battery may be taken into account. Each data estimation model 150 may be based on any one or any combination of any two or more of a neural network (NN), a deep neural network (DNN), a support vector machine (SVM), and a Gaussian process regression (GPR).

In one example, the preprocessor 130 trains an estimation model for each sensor by inputting the various types of data collected by the data collector 110 to a DNN-based data estimation model 150.

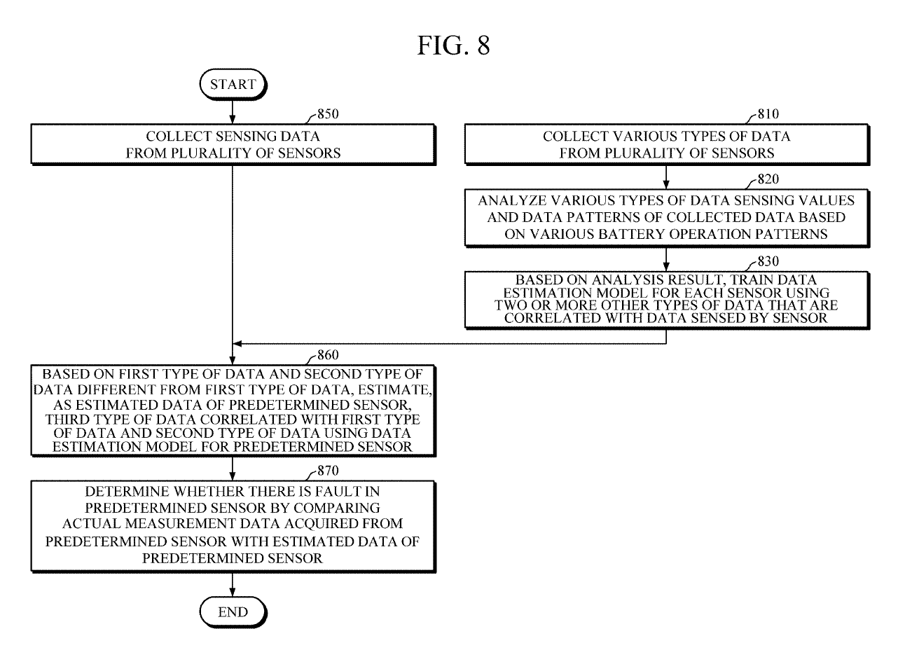

FIG. 8 is a flowchart illustrating an example of a sensor management method using a data estimation model. Hereinafter, a sensor management method of managing each sensor using a sensor management apparatus 200 is described with reference to FIGS. 2 and 8.

A method of training a data estimation model for each sensor may be configured separately from a method of estimating the data of a predetermined sensor using the data estimation model as is described below.

First, the data collector 110 collects sensing data acquired from a plurality of sensors in 810. Then, the preprocessor 130 analyzes various types of data sensing values and data patterns of the collected data based on various battery operation patterns in 820. Then, based on the analysis result, the preprocessor 130 trains a data estimation model for each sensor using two or more other types of data that are correlated with the data sensed by the sensor for which the data estimation model 150 is being trained in 830. A method of training the data estimation model for each sensor may be performed through an additional process prior to a method of estimating of a predetermined sensor. In addition, the data estimation model 150 and a parameter set of the data estimation model 150 for each sensor may be acquired from the outside.

The following is one example in which a sensor management apparatus 100 estimates data of a predetermined sensor. First, the data collector 110 collects sensing data acquired from a plurality of sensors in 850. Then, based on a first type of data and a second type of data different from the first type of data, the estimator 120 estimates, as estimated data of the predetermined sensor, a third type of data correlated with the first type of data and the second type of data using a data estimation model 150 for the predetermined sensor in 860.

Then, the sensor manager 140 determines whether there is a fault in a predetermined sensor by comparing actual measurement data acquired from the predetermined with the estimated data of the predetermined sensor in 870. For example, if a difference between the actual measurement data and the estimated data is greater than a predetermined threshold, the sensor manager 140 determines that there is a fault in the predetermined sensor; or performs other operations to determine whether there is a fault in the predetermined sensor. In one example, when the sensor manager 140 determines that a predetermined sensor has a fault or is malfunctioning, the sensor manager 140 may send a notification about the fault or malfunction in the predetermined sensor to a user.

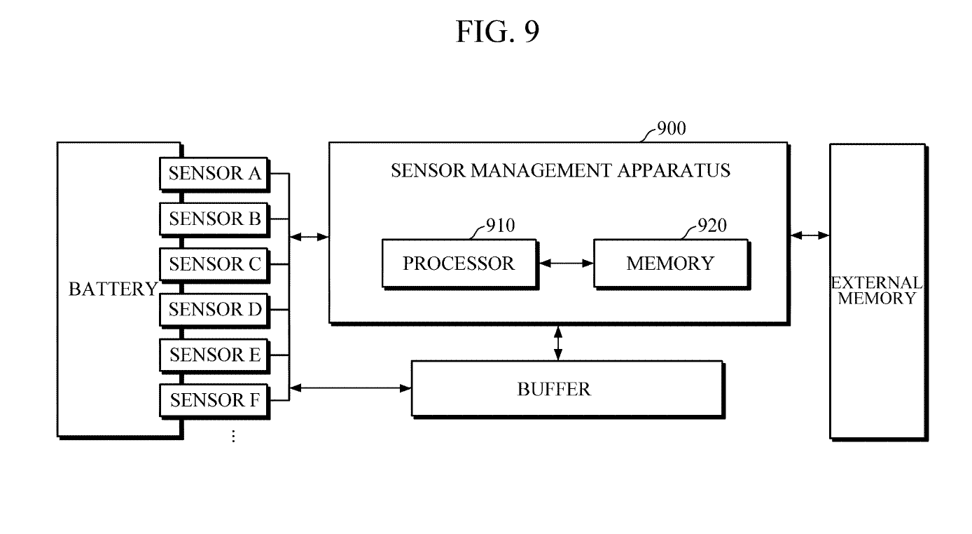

FIG. 9 is a detailed diagram illustrating another example of a sensor management apparatus. A sensor management apparatus 900 includes a processor 910 and a memory 920, and is connected to a plurality of sensors A to F, a buffer, and an external memory. The memory 920 stores instructions that, when executed by the processor 910, cause the processor 910 to perform the functions of the data collector 110, the estimator 120, the preprocessor 130, the sensor manager 140, and the data estimation models 150 illustrated in FIG. 2. In other words, the memory 920 stores instructions that, when executed by the processor 910, configure the processor 910 to implement the data collector 110, the estimator 120, the preprocessor 130, the sensor manager 140, and the data estimation models 150 illustrated in FIG. 2 and perform the functions thereof. The external memory corresponds to the memory illustrated in FIG. 2. The description of the operation of the sensor management apparatus 200 illustrated in FIG. 2 is also applicable to claim 9, and thus will not be repeated here.

Since it is not necessary to provide duplicate sensors of the same type to compensate for a fault in a sensor of that type, the costs and volume of hardware may be reduced.

The data collector 110 and the estimator 120 in FIGS. 1 and 2, the preprocessor 130, the sensor manager 140, and the data estimation models 150 in FIG. 2, the deep neural network (DNN) in FIG. 4, and the processor 910 in FIG. 9 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 6-8 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sensor management apparatus comprising:
a data collector configured to collect various types of data from a plurality of sensors; and
an estimator configured to estimate other types of data based on two or more types of the collected data.

2. The sensor management apparatus of claim 1, wherein at least some of the plurality of sensors are inside a battery; and
the data collector is further configured to collect, as at least part of the various types of data, any one or any combination of any two or more of voltage data, current data, and temperature data sensed by at least some of the sensors inside the battery.

3. The sensor management apparatus of claim 1, wherein the estimator is further configured to estimate, as part of the other types of data, a third type of data correlated with a first type of data and a second type of data different from the first type of data based on the first type of data and the second type of data.

4. The sensor management apparatus of claim 3, wherein there is an interdependence between data patterns of the first type of data and the third type of data, and an interdependence between data patterns of the second type of data and the third type of data; and
the estimator is further configured to estimate the third type of data based on the first type of data and the second type of data using a pre-stored data estimation model trained based on the interdependences.

5. The sensor management apparatus of claim 1, further comprising a preprocessor configured to train a data estimation model for each sensor of the plurality of sensors.

6. The sensor management apparatus of claim 5, wherein the preprocessor is further configured to:
analyze various types of data sensing values and data patterns of the collected data based on various battery operation patterns, and
based on a result of the analyzing, train the data estimation model for each sensor using the two or more types of the collected data.

7. The sensor management apparatus of claim 6, further comprising:
a memory configured to store the data estimation model for each sensor; and
a buffer configured to store the various types of data sensing values and data patterns of the collected data.

8. The sensor management apparatus of claim 5, wherein the data estimation model for each sensor is based on any one or any combination of any two or more of a neural network (NN), a deep neural network (DNN), a support vector machine (SVM), and a Gaussian process regression (GPR).

9. The sensor management apparatus of claim 7, wherein the data estimation model for each sensor is a DNN-based data estimation model; and
the preprocessor is further configured to:
input the two or more types of the collected data to the DNN-based data estimation model, and
train the DNN-based data estimation model to estimate data of a predetermined sensor based on a data correlation between the data of the predetermined sensor and the two or more types of the collected data.

10. The sensor management apparatus of claim 1, wherein the estimator is further configured to estimate data of a predetermined sensor of the plurality of sensors based on the two or more types of the collected data; and
the apparatus further comprises a sensor manager configured to compare actual measurement data acquired from the predetermined sensor with the estimated data of the predetermined sensor, and determine whether there is a fault in the predetermined sensor based on a result of the comparing.

11. A sensor management method comprising:
collecting various types of data from a plurality of sensors; and
estimating other types of data based on two or more types of the collected data.

12. The sensor management method of claim 11, wherein at least some of the plurality of sensors are inside a battery; and
the collecting of the various types of data comprises collecting, as at least part of the various types of data, any one or any combination of any two or more of voltage data, current data, and temperature data sensed by at least some of the sensors inside the battery.

13. The sensor management method of claim 11, wherein the estimating of other types of data comprises estimating, as part of the other types of data, a third type of data correlated with a first type of data and a second type of data different from the first type of data based on the first type of data and the second type of data.

14. The sensor management method of claim 13, wherein there is an interdependence between data patterns of the first type of data and the second type of data, and an interdependence between data patterns of the second type of data and the third type of data; and
the estimating of the third type of data comprises estimating the third type of data based on the first type of data and the second type of data using a pre-stored data estimation model trained based on the interdependences.

15. The sensor management method of claim 11, further comprising training a data estimation model for each sensor of the plurality of sensors.

16. The sensor management method of claim 15, wherein the training comprises:
analyzing various types of data sensing values and data patterns of the collected data based on various battery operation patterns; and
based on a result of the analyzing, training the data estimation model for each sensor using the two or more types of the collected data.

17. The sensor management method of claim 15, wherein the data estimation model for each sensor is based on any one or any combination of any two or more of a neural network (NN), a deep neural network (DNN), a support vector machine (SVM), and a Gaussian process regression (GPR).

18. The sensor management method of claim 17, wherein the data estimation model for each sensor is a DNN-based estimation model; and
the training comprises:
inputting the two or more types of the collected data to the DNN-based data estimation model; and
training the DNN-based estimation model to estimate data of a predetermined sensor based on a data correlation between the data of the predetermined sensor and the two or more types of the collected data.

19. The sensor management method of claim 11, wherein the estimating comprises estimating data of a predetermined sensor of the plurality of sensors based on the two or more types of the collected data; and
the method further comprises:
comparing actual measurement data acquired from the predetermined sensor with the estimated data of the predetermined sensor; and
determining whether there is a fault in the predetermined sensor based on a result of the comparing.

20. A non-transitory computer-readable storage medium storing instructions that, when executed by a processor, cause the processor to perform the sensor management method of claim 11.

21. A sensor management apparatus comprising:
a processor configured to:
collect different types of data from a plurality of sensors, and
estimate data of a faulty sensor based on two or more other types of data of the collected data.

22. The sensor management apparatus of claim 21, further comprising a memory configured to store instructions;
wherein the processor is further configured to execute the instructions to configure the processor to:
collect different types of data from a plurality of sensors, and
estimate data of a faulty sensor based on two or more other types of data of the collected data.

23. The sensor management apparatus of claim 21, wherein there is only one sensor for each different type of data.

24. The sensor management apparatus of claim 21, wherein the processor is further configured to estimate the data of the faulty sensor based on two or more other types of data of the collected data that are correlated with data of the faulty sensor obtained while the faulty sensor is operating normally.

25. The sensor management apparatus of claim 24, wherein the processor is further configured to estimate the data of the faulty sensor based on two or more other types of data of the collected data that are correlated with the data of the faulty sensor using a data estimation model for the faulty sensor that is trained based on the correlation between the data of the faulty sensor obtained while the faulty sensor is operating normally and the two or more other types of data of the collected data that are correlated with the data of the faulty sensor obtained while the faulty sensor is operating normally.

26. The sensor management apparatus of claim 25, wherein the processor is further configured to train the data estimation model for the faulty sensor based on the data of the faulty sensor obtained while the faulty sensor is operating normally and the two or more other types of data of the collected data that are correlated with the data of the faulty sensor obtained while the faulty sensor is operating normally.
